(19) United States
(12) Patent Application Publication
(10) Pub. No.: US 2013/0146876 A1
(43) Pub. Date: Jun. 13, 2013

(54) THIN FILM TRANSISTOR ARRAY SUBSTRATE AND MANUFACTURING METHOD THEREOF

(71) Applicant: Shijian Qin, Shenzhen (CN)

(72) Inventor: Shijian Qin, Shenzhen (CN)

(73) Assignee: Shenzhen China Star Optoelectronics Technology Co., Ltd., Shenzhen (CN)

(21) Appl. No.: 13/380,900

(22) PCT Filed: Dec. 13, 2011
(86) PCT No.: PCT/CN11/83871

§ 371 Date: Dec. 26, 2011

(30) Foreign Application Priority Data
Dec. 7, 2011 (CN) 201110403568.4

(51) Int. Cl. H01L 33/08; H01L 33/36

(52) U.S. Cl. 257/59; 438/34; 257/71; 257/E33.053

(57) ABSTRACT

A manufacturing method of a thin film transistor array substrate includes the following two steps: depositing a first metal layer on a substrate; and processing the first metal layer through coating photoresist, exposing, developing, etching, and stripping photoresist processes to form a light blocking metal portion and a lower electrode of a first storage capacitor simultaneously. With the manufacturing method of the present disclosure, the light blocking metal portion can protect components of TFTs from being exposed to strong light during the manufacturing process, which can improve a stability of the TFT.

### BACKGROUND

1. Technical Field

The present disclosure relates to liquid crystal displays and, particularly, to a thin film transistor array substrate and a manufacturing method thereof.

2. Description of Related Art

With the prevailing use of thin film transistors (TFTs) in liquid crystal display (LCDs), people have paid a lot of attention to the quality of the TFT LCD. The TFT LCD often includes a TFT array substrate which is manufactured by five photo-mask processes. Generally, the five photo-mask processes includes a gate photo-mask process, an active layer photo-mask process, a source/drain (S/D) photo-mask process, a via hole photo-mask process, and a pixel electrode photo-mask process. Each of the photo-mask processes may further include at least one film depositing sub-process and etching process. That is, during the manufacturing process of the TFT array substrate, the components thereof may be exposed to strong light frequently. This may reduce a stability of the TFT. In another aspect, the conventional TFT array substrate often includes at least one storage capacitor, and an area of the at least one storage capacitor may be increased for increasing the capacitance of the at least one storage capacitor occasionally. However, this reduces an aperture ratio of the TFT array substrate.

Therefore, there is room for improvement in the art.

### SUMMARY

The present disclosure provides a manufacturing method of a thin film transistor array substrate. The manufacturing method includes the following steps:

depositing a first metal layer on a substrate; and

processing the first metal layer through coating photoresist, exposing, developing, etching, and stripping photoresist processes to form a light blocking metal portion and a lower electrode of a first storage capacitor simultaneously.

Preferably, the manufacturing method further includes:
depositing a first insulating layer made of silicon nitride to cover the light blocking metal portion and the lower electrode of the first storage capacitor.

Preferably, the manufacturing method further includes:
depositing a second metal layer on the substrate having the light blocking metal portion and lower electrode of the first storage capacitor, processing the second metal layer through the coating photoresist, exposing, developing, etching, and stripping photoresist processes to form an upper electrode of the first storage capacitor on the substrate.

Preferably, the step of processing the second metal layer through the coating photoresist, exposing, developing, etching, and stripping photoresist processes to form an upper electrode of the first storage capacitor on the substrate specifically includes:
depositing an ohmic contacting layer on the second metal layer, processing the ohmic contacting layer and the second metal layer through coating photoresist, exposing, developing, etching, and stripping photoresist processes to obtain the upper electrode of the first storage capacitor as well as data lines, a source electrode, and a drain electrode all of which are covered by the processed ohmic contacting layer.

Preferably, the manufacturing method further includes:
depositing a semiconductor layer, a second insulating layer, and a third metal layer covering the processed ohmic contacting layer on the substrate; and
processing the semiconductor layer, the second insulating layer, and the third metal layer through coating photoresist, exposing, developing, etching, and stripping photoresist processes, and removing parts of the processed ohmic contacting layer respectively partly covering the drain electrode and covering the upper electrode of the first storage capacitor simultaneously.

Preferably, the manufacturing method further includes:
forming a protective layer covering the processed third metal layer, the part of the drain electrode, the first insulating layer, and the upper electrode of the first storage capacitor on the substrate;
defining a first through hole and a second through hole in the protective layer through the coating photoresist, exposing, developing, etching, and stripping photoresist processes; and
depositing an indium tin oxide film on the protective layer, connecting the indium tin oxide film with the drain electrode via the first through hole to form a pixel electrode and with the lower electrode of the first storage capacitor via the second through hole to be an upper electrode of a second storage capacitor.

Preferably, the upper electrode of the first storage capacitor can also work as a lower electrode of the second storage capacitor, and the first storage capacitor and the second storage capacitor are connected to each other in parallel to form a storage capacitor of a pixel

The present disclosure also provides another manufacturing method of a thin film transistor array substrate. The manufacturing method includes the two following steps:
depositing a first metal layer on a substrate; and
processing the first metal layer through coating photoresist, exposing, developing, etching, and stripping photoresist processes to form a light blocking metal portion.

Preferably, the manufacturing method further includes:
processing the first metal layer through the coating photoresist, exposing, developing, etching, and stripping photoresist processes to form an lower electrode of a first storage capacitor.

Preferably, the manufacturing method further includes:
depositing a second metal layer on the substrate having the light blocking metal portion and lower electrode of the first storage capacitor, processing the second metal layer through the coating photoresist, exposing, developing, etching, and stripping photoresist process to form an upper electrode of the first storage capacitor on the substrate.

Preferably, the upper electrode of the first storage capacitor can also work as a lower electrode of a second storage capacitor of the thin film transistor array substrate, and the second storage capacitor is connected to the first storage capacitor in parallel to form a storage capacitor of a pixel.

Preferably, the manufacturing method further includes:
depositing a first insulating layer made of silicon nitride on the substrate having light blocking metal portion.

The present disclosure still further provides a thin film transistor array substrate. The thin film transistor array substrate include a glass substrate, a first insulating layer, and a light blocking metal portion formed by processing a first metal layer deposited on the glass substrate through coating photoresist, exposing, developing, etching, and stripping photoresist processes.

Preferably, the thin film transistor array substrate further comprises a lower electrode of a first storage capacitor formed by processing the first metal layer through the coating photoresist, exposing, developing, etching, and stripping photoresist processes.

Preferably, the thin film transistor array substrate further includes a second metal layer deposited on the first insulating layer, and the second metal layer is processed through the coating photoresist, exposing, developing, etching, and stripping photoresist processes to form an upper electrode of the first storage capacitor.

Preferably, the upper electrode of the first storage capacitor can also work as a lower electrode of a second storage capacitor, and the second storage capacitor is connected to the first storage capacitor in parallel to form a storage capacitor of a pixel.

Preferably, an area of the upper electrode of the first storage capacitor is smaller than that of the lower electrode of the first storage capacitor.

With the manufacturing method of the thin film transistor array substrate, the light blocking metal portion is formed on the substrate by processing the first metal layer. The light blocking metal portion is capable of preventing TFTs from being exposed to strong light during the manufacturing process of the TFT array substrate. Additionally, the second storage capacitor is connected to the first storage capacitor in parallel to form the storage capacitor, thus, the capacitance of the storage capacitor can be increased without increasing an area thereof and without reducing an aperture ratio of the TFT array substrate.

### DESCRIPTION OF THE DRAWINGS

Many aspects of the embodiments can be better understood with reference to the following drawings. The components in the drawings are not necessarily dawns to scale, the emphasis instead being placed upon clearly illustrating the principles of the embodiments. Moreover, in the drawings, like reference numerals designate corresponding parts throughout the several views.

FIG. 1 is a flow chart of a manufacturing method of a TFT array substrate in accordance with a first embodiment of the present disclosure.

FIG. 2 is a flow chart of a manufacturing method of a TFT array substrate in accordance with a second embodiment of the present disclosure.

FIG. 3 is a schematic view after the process of forming a light blocking metal portion and a lower electrode of the first storage capacitor on a glass substrate.

FIG. 4 is a schematic view after the process of forming an upper electrode of the first storage capacitor based on the process of FIG. 3.

FIG. 5 is a schematic view after the process of etching and removing an ohmic contacting layer and a gate electrode based on the process of FIG. 4.

FIG. 6 is a schematic view after the process of forming an upper electrode of a second storage capacitor based on the process of FIG. 5.

### DETAILED DESCRIPTION

The disclosure is illustrated by way of example and not by way of limitation in the figures of the accompanying drawings in which like references indicate similar elements. It should be noted that references to “an” or “one” embodiment is this disclosure are not necessarily to the same embodiment, and such references mean at least one.

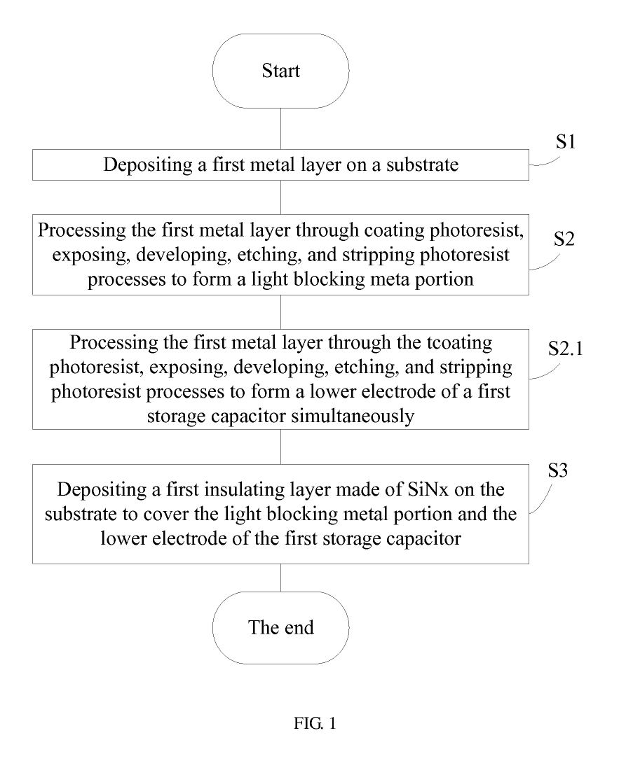

Referring to FIG. 1, which illustrates a manufacturing method of a thin film transistor (TFT) array substrate in a first embodiment, the manufacturing method includes the following steps.

Step S1, depositing a first metal layer on a substrate which has been pre-cleaned. In the embodiment, the first metal layer is deposited on the substrate by a vacuum sputtering method and is made of molybdenum or aluminum or other opaque metal.

Step S2, processing coating photoresist, exposing, developing, wet-etching, and stripping photoresist processes to the first metal layer to form a light blocking metal portion.

Step S2.1, processing the coating photoresist, exposing, developing, wet-etching, and stripping photoresist processes to the first metal layer to form the light blocking metal portion and a lower electrode of a first storage capacitor simultaneously. The light blocking metal portion and the lower electrode of the first storage capacitor are separated from each other. The light blocking metal portion can protect components of TFTs from being exposed to strong light during the exposing processes and thus improving a stability of the TFTs.

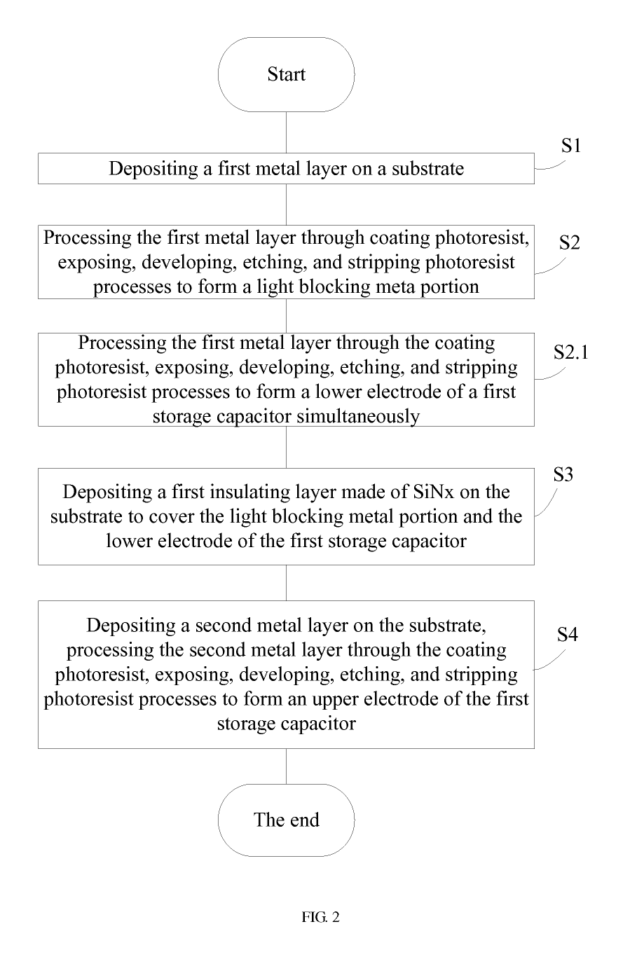

Step S3, depositing a first insulating layer covering the light blocking layer and the lower electrode of the first storage capacitor on the substrate. The first insulating layer can be formed by a plasma enhanced chemical vapor deposition (PECAD) method and can be made of SiNx. Referring to FIG. 2, in a second embodiment, the manufacturing method of the TFT array substrate compared with that of the first embodiment further includes the following steps.

Step S4, depositing a second metal layer on the substrate having the light blocking metal portion and the lower electrode of the first storage capacitor, and processing the coating photoresist, exposing, developing, wet-etching, and stripping photoresist processes to the second metal layer to form an upper electrode of the first storage capacitor.

Specifically, first, depositing the second metal layer on the first insulating layer on the substrate having the light blocking metal portion and the lower electrode of the first storage capacitor by the vacuum sputtering process, second, depositing an ohmic contacting layer on the second metal layer by PEVCD, third, processing the coating photoresist, exposing and developing processes to the second metal layer and the ohmic contacting layer, forth, etching the ohmic contacting layer by dry-etching, fifth, etching the second metal layer by wet-etching, sixth, processing the stripping photoresist process. And then the upper electrode of the first storage capacitor, the data lines, the source electrode and the drain electrode are obtained, furthermore, the data lines, the source electrode and the drain electrode are covered by the ohmic contacting layer.

Step S5, depositing a semiconductor layer on the ohmic contacting layer covering the data lines, the source electrode and the drain electrode by the PECVD method. The semiconductor layer at the same time covers a part of the first insulating layer defined between the source electrode and the drain electrode, and is made of amorphous silicon (abbreviated to a-Si).

Step S6, depositing a second insulating layer made of silicon nitride (SiNx) on the semiconductor layer.

Step S7, depositing a third metal layer on the second insulating layer.

Step S8, processing the coating photoresist, exposing and developing processes to the third metal layer, the second insulating layer and the semiconductor layer. And then etching the third metal layer, the second insulating layer and the semiconductor layer are processing. First, etching the third metal layer by wet-etching, second, etching the second insulating layer and the semiconductor layer by dry-etching. And finally, processing the stripping photoresist process. At this time, the processed ohmic contacting layer covering on the drain electrode and the upper electrode of the first storage capacitor is removed by etching.

Step S9, depositing a protective layer on the substrate by the PECVD method, and processing the coating photoresist, exposing, developing, dry-etching and stripping photoresist processes to the protective layer. A mask using in the exposing process is a half tone mask. A first through hole 1 and a second through hole 2 are defined in the protective layer by dry-etching. The protective layer at this time covers the gate electrode, the part of the drain electrode exposed outside, the first insulating layer and the upper electrode of the first storage capacitor.

Step S10, depositing an indium tin oxide (ITO) film on the protective layer by the vacuum sputtering method. The ITO film in this state is electrically connected to the drain electrode via the first through hole 1 to form a pixel electrode and is electrically connected to the lower electrode of the first storage capacitor via the second through hole 2 to form an upper electrode of a second storage capacitor. The upper electrode of the first storage capacitor can also be used as a lower electrode of the second storage capacitor, and the lower electrode of the second storage capacitor, the ITO film are connecting to the lower electrode of the first storage capacitor via the second through hole 2 to form the second storage capacitor. And the first storage capacitor is connecting to the second storage capacitor in parallel to form a storage capacitor of the pixel.

In the above manufacturing method, the light blocking metal portion is formed on the substrate with the ohmic contacting layer, the source electrode, the drain electrode, the gate electrode formed thereon, thus, the components of TFTs can be protected from being exposed to strong lights in the exposing processes. Additionally, in the above manufacturing method, the upper electrode of the first storage capacitor is capable of working as the lower electrode of the second storage capacitor. The lower electrode of the second capacitor and the upper electrode of the second capacitor formed by the ITO film connecting the lower electrode 81 of the first capacitor via t he through hole 2 form the second capacitor. Therefore, the second storage capacitor can be connected to the first storage capacitor in parallel to form the storage capacitor of the pixel. Also, since the first and second storage capacitors are connected to each other in parallel, an area of the storage capacitor is reduced to improve an aperture ratio of the TFT array substrate.

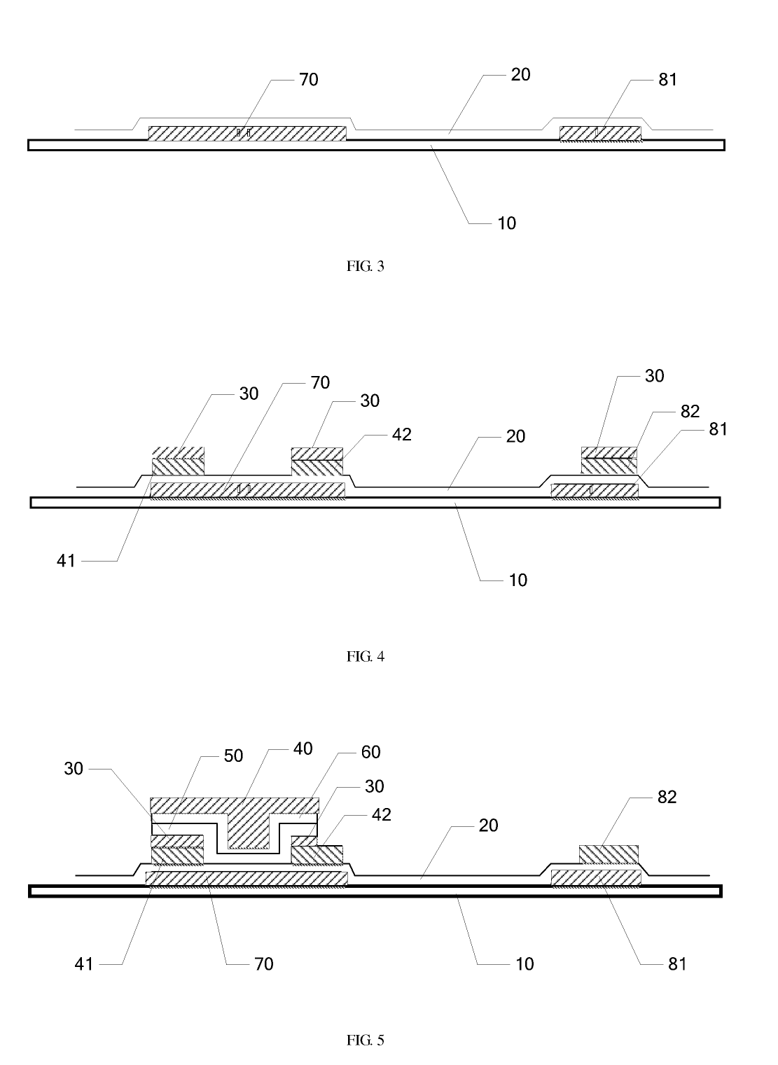

Referring to FIG. 3, which is a schematic view after the process of forming a light blocking metal portion and a lower electrode of the first storage capacitor on a glass substrate. A TFT array substrate in an embodiment include a glass substrate 10. A first metal layer is deposited on the glass substrate 10 and is further processed through coating photoresist, exposing, developing, wet-etching, and stripping photoresist processes to form a light blocking metal portion 70 and a lower electrode 81. The lower electrode 81 is separated from the light blocking layer 70. The light blocking metal portion 70 is formed on the glass substrate 10, thus, the components of TFTs can be protected from being exposed to strong lights in the exposing processes.

A first insulating layer 20 is deposited on the glass substrate 10 and covers the light blocking metal portion 70 and the lower electrode 81. In the embodiment, the first insulating layer 20 is formed by the PECVD method and made of insulating material such as SiNx.

Referring to FIG. 4, which is a schematic view after the process of forming an upper electrode of the first storage capacitor based on the process of FIG. 3. A second metal layer is deposited on first insulating layer 20 by the vacuum sputtering method. A ohmic contacting layer 30 is formed on the second metal layer by the PECVD method. The second metal layer and the ohmic contacting layer 30 are processed by the coating photoresist, exposing, and developing processes. After that, the ohmic contacting layer 30 is processed by the dry-etching process and then the second metal layer is etched by the wet-etching process. After the ohmic contacting layer 30 and the second metal layer are etched, the coated photoresist is stripped to obtain an upper electrode 82. In the embodiment, an area of the upper electrode 82 of the first storage capacitor is smaller than that of the low electrode 81 of the first storage capacitor.

With the same method of forming the upper electrode 82, data lines, a source electrode 41, and a drain electrode 42 are also formed. And the data lines, the source electrode 41, and the drain electrode 42 are all covered by the processed ohmic contacting layer 30.

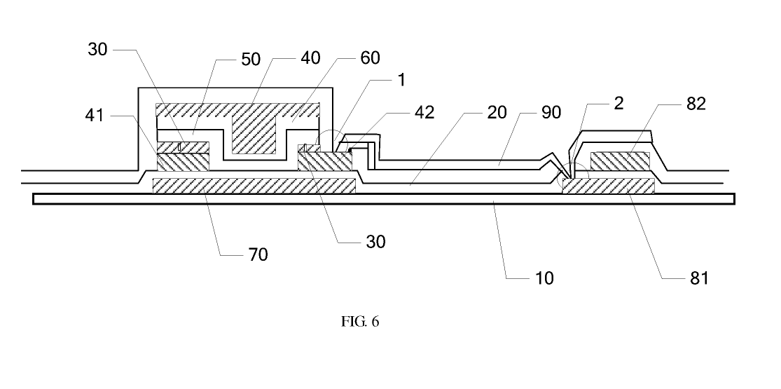

Referring to FIG. 5, which is a schematic view after the process of etching and removing an ohmic contacting layer and a gate electrode based on the process of FIG. 4. A semiconductor layer 50 is deposited on the glass substrate 10. In some embodiments, the semiconductor layer 50 is deposited on the processed ohmic contacting layer 50 and the glass substrate 10 by the PECVD method and can be made of a-Si. A second insulating layer 60 is deposited on the the semiconductor layer 50 and can be made of SiNx. A third metal layer is deposited on the second insulating layer 60 by the vacuum spurting method. The third metal layer, the semiconductor layer 50, and the second insulating layer 60 then are processed by the coating photoresist, exposing, and developing processes. After that, the third metal layer is etched by the wet-etching process and then the semiconductor layer 50 and the second insulating layer 60 are etched by the dry-etching processes. And then, the coated photoresist is stripped. At this time, a part of the processed ohmic contacting layer 30 covering the drain electrode 42 and covering the upper electrode 82 are removed, a gate electrode 40 is formed.

Referring to FIG. 6, a protective layer is deposited on the substrate 10 by PEVCD method, and covers the gate electrode 40, the part of the drain electrode 42 exposed outside, the part of the first insulating layer 20 between the drain electrode 42 and the upper electrode 82. After processing the coating photoresist, exposing, developing, dry-etching and stripping photoresist processes, a first through hole 1 and a second through hole 2 are defined in the protective layer. It is noted that the mask using in the exposing process here is a half tone mask.

The ITO film 90 is deposited on the processed protective layer by the vacuum sputtering method and is processed to form an upper electrode of a second storage capacitor and a pixel ITO electrode. Specifically, the ITO film 90 is connected to the drain electrode 42 via the first through hole 1 to form the pixel electrode, and is connected to the lower electrode 81 of the first storage capacitor to form the upper electrode of the second storage capacitor. The upper electrode of the second storage capacitor corresponds to the upper electrode 82 of the first storage capacitor to allow the upper electrode 82 of the first storage capacitor to be the lower electrode of the second storage capacitor.

In the TFT array substrate, the light blocking metal portion 70 is formed on the substrate 10 for preventing the components of TFTs from being exposed to strong light. This improves the stability of the TFTs.

In the above manufacturing method, the upper electrode of the first storage capacitor is capable of working as the lower electrode of the second storage capacitor. The lower electrode of the second capacitor and the upper electrode of the second capacitor formed by the ITO film connecting the lower electrode 81 of the first capacitor via the through hole 2 form the second capacitor. Therefore, the second storage capacitor can be connected to the first storage capacitor in parallel to form the storage capacitor of the pixel.

In the TFT array substrate, the upper electrode 82 of the first storage capacitor can also be used as the lower electrode of the second storage capacitor, thus, the second storage capacitor can be connected to the first storage capacitor in parallel to form the storage capacitor of the pixel. In this way, the area of the storage capacitor can be decreased when the capacitance thereof is increased to increase the aperture ratio of the corresponding pixel.

Even though information and the advantages of the present embodiments have been set forth in the foregoing description, together with details of the mechanisms and functions of the present embodiments, the disclosure is illustrative only; and that changes may be made in detail, especially in matters of shape, size, and arrangement of parts within the principles of the present embodiments to the full extend indicated by the broad general meaning of the terms in which the appended claims are expressed.

What is claimed is:

1. A manufacturing method of a thin film transistor array substrate, wherein the manufacturing method comprises:
depositing a first metal layer on a substrate; and
processing the first metal layer through coating photoresist, exposing, developing, etching, and stripping photoresist processes to form a light blocking metal portion and a lower electrode of a first storage capacitor simultaneously.

2. The manufacturing method of claim 1, wherein the manufacturing method further comprises: depositing a first insulating layer made of silicon nitride to cover the light blocking metal portion and the lower electrode of the first storage capacitor on the substrate.

3. The manufacturing method of claim 1, wherein the manufacturing method further comprises: depositing a second metal layer on the substrate having the light blocking metal portion and lower electrode of the first storage capacitor, processing the second metal layer through the coating photoresist, exposing, developing, etching, and stripping photoresist processes to form an upper electrode of the first storage capacitor.

4. The manufacturing method of claim 3, wherein the step of processing the second metal layer through the coating photoresist, exposing, developing, etching, and stripping photoresist processes to form an upper electrode of the first storage capacitor specifically comprises:
depositing an ohmic contacting layer on the second metal layer, processing the ohmic contacting layer and the second metal layer through the coating photoresist, exposing, developing, etching, and stripping photoresist processes to obtain the upper electrode of the first storage capacitor as well as data lines, a source electrode, and a drain electrode all of which are covered by the processed ohmic contacting layer.

5. The manufacturing method of claim 4, wherein the manufacturing method further comprises:
depositing a semiconductor layer, a second insulating layer, and a third metal layer covering the processed ohmic contacting layer on the substrate; and
processing the semiconductor layer, the second insulating layer, and the third metal layer through the coating photoresist, exposing, developing, etching, and stripping photoresist processes, and removing parts of the processed ohmic contacting layer respectively partly covering the drain electrode and covering the upper electrode of the first storage capacitor.

6. The manufacturing method of claim 5, wherein the manufacturing method further comprises:
forming a protective layer covering the processed third metal layer, the part of the drain electrode without the processed ohmic contacting layer deposited thereon, the first insulating layer, and the upper electrode of the first storage capacitor on the substrate;
defining a first through hole and a second through hole in the protective layer through the coating photoresist, exposing, developing, etching, and stripping photoresist processes; and
depositing an indium tin oxide film on the protective layer, connecting the indium tin oxide film with the drain electrode via the first through hole to form a pixel electrode and with the lower electrode of the first storage capacitor via the second through hole to be an upper electrode of a second storage capacitor.

7. The manufacturing method of claim 6, wherein the upper electrode of the first storage capacitor can also work as a lower electrode of the second storage capacitor, and the first storage capacitor and the second storage capacitor are connected to each other in parallel to form a storage capacitor of a pixel.

8. A manufacturing method of a thin film transistor array substrate, wherein the manufacturing method comprises:
depositing a first metal layer on a substrate; and
processing the first metal layer through coating photoresist, exposing, developing, etching, and stripping photoresist processes to form a light blocking metal portion.

9. The manufacturing method of claim 8, wherein the manufacturing method further comprises:
processing the first metal layer through the coating photoresist, exposing, developing, etching, and stripping photoresist processes to form an lower electrode of a first storage capacitor.

10. The manufacturing method of claim 9, wherein the manufacturing method further comprises:
depositing a second metal layer on the substrate having the light blocking metal portion and lower electrode of the first storage capacitor, processing the second metal layer through the coating photoresist, exposing, developing, etching, and stripping photoresist process to form an upper electrode of the first storage capacitor.

11. The manufacturing method of claim 10, wherein the upper electrode of the first storage capacitor can also work as a lower electrode of a second storage capacitor, and the second storage capacitor is connected to the first storage capacitor in parallel to form a storage capacitor of a pixel.

12. The manufacturing method of claim 11, wherein the manufacturing method further comprises:
depositing a first insulating layer made of silicon nitride on the substrate having light blocking metal portion.

13. A thin film transistor array substrate, wherein the thin film transistor array substrate comprises:
a glass substrate;
a first insulating layer; and
a light blocking metal portion formed by processing a first metal layer deposited on the glass substrate through coating photoresist, exposing, developing, etching, and stripping photoresist processes.

14. The thin film transistor array substrate of claim 13, wherein the thin film transistor array substrate further comprises a lower electrode of a first storage capacitor formed by processing the first metal layer through the coating photoresist, exposing, developing, etching, and stripping photoresist processes.

15. The thin film transistor array substrate of claim 14, wherein the thin film transistor array substrate further comprises a second metal layer deposited on the first insulating layer, the second metal layer is processed through the coating photoresist, exposing, developing, etching, and stripping photoresist processes to form an upper electrode of the first storage capacitor.

16. The thin film transistor array substrate of claim 15, wherein the upper electrode of the first storage capacitor can also be used as a lower electrode of a second storage capacitor, and the second storage capacitor is connected to the first storage capacitor in parallel to form a storage capacitor of a pixel.

17. The thin film transistor array substrate of claim 16, wherein an area of the upper electrode of the first storage capacitor is smaller than that of the lower electrode of the first storage capacitor.
